(19) United States
(12) Patent Application Publication
(10) Pub. No.: US 2011/0263067 A1
(43) Pub. Date: Oct. 27, 2011

(54) Methods of Forming a Concentrating Photovoltaic Module

(75) Inventors: Sunil Vaid, North Brunswick, NJ (US); Mikhail Kats, Rockaway, NJ (US); Gary Hering, Belle Mead, NJ (US)

(73) Assignee: Emcore Solar Power, Inc., Albuquerque, NM (US)

(21) Appl. No.: 13/156,064

(22) Filed: Jun. 8, 2011

Related U.S. Application Data
(63) Continuation-in-part of application No. 12/582,047, filed on Oct. 20, 2009.
Application No. 12/582,047 is a continuation-in-part of application No. 12/069,642, filed on Feb. 11, 2008.
(60) Provisional application No. 61/471,327, filed on Apr. 4, 2011.

(51) Int. Cl. H01L 31/0232

(52) U.S. Cl. 438/65; 257/E31.127

(57) ABSTRACT

Solar cell modules for converting solar energy into electrical energy. The modules includes a housing formed from three separate members that are attached together to form an interior space. A top member extends across an open side of the housing and includes one or more lenses. One or more solar cell receivers are positioned within the interior space of the house and are aligned with one or more of the lenses to receive and convert the solar energy into electrical energy.

### PRIORITY

The present application is a continuation-in-part of Ser. No. 12/582,047 filed Oct. 20, 2009, which itself is a continuation-in-part of Ser. No. 12/069,642 filed Feb. 11, 2008. The present application also claims priority to Ser. No. 61/471,327 filed Apr. 4, 2011. Each of these is herein incorporated by reference in their entirety.

### BACKGROUND

Satisfying the world's growing demand for energy is one of the most significant challenges facing society. At present, about 85% of the energy produced in the United States comes from fossil fuels. Given that the supply of such fuels is on the decline, their prices continue to rise, and the resultant greenhouse gases may contribute to global warming, there is a need to develop new technologies that are economically feasible and environmentally friendly.

Solar energy is one technology for power generation that is clean, quiet and renewable. It is also plentiful: with an average of roughly 125,000 terawatts of solar energy reaching the planet at any given time, solar technology can potentially generate a significant amount of energy.

Solar array modules are constructed to convert the solar energy into electrical energy. The modules include a housing, and a number of lenses that direct solar energy to corresponding solar cell receivers.

The modules are often placed outdoors in various environmental conditions that may include extreme heat, cold, humidity, rain, snow, and ice. The outer housing protects the solar cell receivers from environmental conditions. The outer housing also forms a body to position each of the lenses relative to a corresponding solar cell receiver.

### SUMMARY

The present application is directed to methods of forming a solar cell module for use in a terrestrial solar tracking photovoltaic array. One method includes deforming an enlarged first sheet into three substantially planar sections including a bottom side and opposing first and second lateral sides with the lateral sides being transverse to the bottom side. The method includes attaching a second sheet to exposed first ends of the bottom side and the lateral sides with the second sheet being smaller than the first sheet. The method includes attaching a third sheet to exposed second ends of the bottom side and the lateral sides with the third sheet being smaller than the first sheet. The method includes positioning a plurality of solar cell receivers at the bottom side with each of the plurality of solar cell receivers including a solar cell. The method further includes attaching a top member to exposed upper ends of each of the lateral sides, second sheet, and third sheet. The top member includes a plurality of lenses with each of the lenses aligning with one of the corresponding solar cell receivers.

Another method is directed to forming a solar cell module for use in a terrestrial solar tracking photovoltaic array. The method includes constructing a housing from a first sheet forming three sides of the housing, a second sheet that forms a fourth side of the housing, and a third sheet that forms a fifth side of the housing. The housing forms an interior space with a bottom and outwardly extending sides with an open top side opposite from the bottom side. The method includes positioning a plurality of solar cells receivers through openings in the bottom side with each of the solar cell receivers including a solar cell that is positioned within the interior space and a base positioned out of the interior space. The method includes attaching a top member across the open top side and enclosing the interior space.

Another method is directed to forming a solar cell module for use in a terrestrial solar tracking photovoltaic array. The method includes constructing a first portion of a housing by deforming an enlarged first sheet into three substantially planar sections including a bottom side and opposing first and second lateral sides, with a first angled section between the bottom side and the first lateral side and a second angled section between the bottom side and the second lateral side. The method includes attaching a first end member to exposed first ends of the bottom side and the lateral sides. The method includes attaching a second end member to second ends of the bottom side and the lateral sides with the housing forming an interior space between the bottom side and the lateral sides and the end members that extend outward above the bottom side, and the housing having an open top side opposite from the bottom side. The method includes attaching a plurality of solar cells receivers to the bottom side with each of the solar cell receivers including a solar cell that is positioned within the interior space. The method further includes attaching a top member to exposed upper ends of each of the lateral sides and the end members with the top member including a plurality of lenses with each of the lenses aligning with one of the corresponding solar cell receivers.

Of course, the present invention is not limited to the above features and advantages. Those skilled in the art will recognize additional features and advantages upon reading the following detailed description, and upon viewing the accompanying drawings.

### BRIEF DESCRIPTION OF THE DRAWINGS

The present invention will be now described more fully hereinafter with reference to the accompanying drawings, in which some, but not all embodiments of the invention are shown. Drawings illustrating the embodiments are not-to-scale schematic representations. For the purpose of the present description and of the appended claims, all ranges include the maximum and minimum points disclosed and include any intermediate ranges therein, which may or may not be specifically enumerated herein.

FIG. 1 is a partial perspective view of a terrestrial solar tracking photovoltaic array that includes solar cell modules.

FIG. 2 is a perspective view of a pair of solar cell modules mounted on a frame of a terrestrial solar tracking photovoltaic array.

FIG. 3 is a perspective view of a mount of a terrestrial solar tracking photovoltaic array.

FIG. 4 is an exploded perspective view of a housing of a solar cell module.

FIG. 5 is a perspective view of a housing of a solar cell module.

FIG. 6 is an exploded perspective view of a solar cell module.

FIG. 7 is a perspective view of a solar cell module.

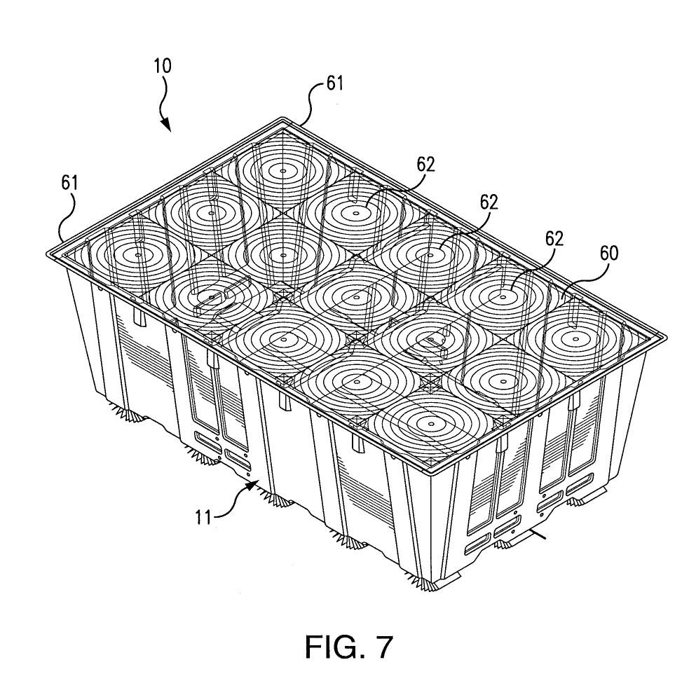

FIG. 8 is a perspective view of an interior of a solar cell module.

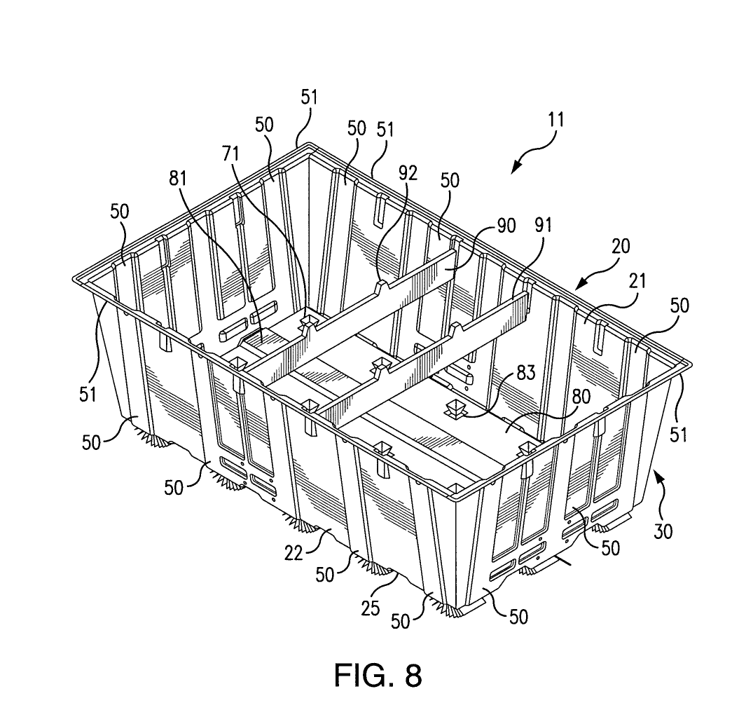

### DETAILED DESCRIPTION

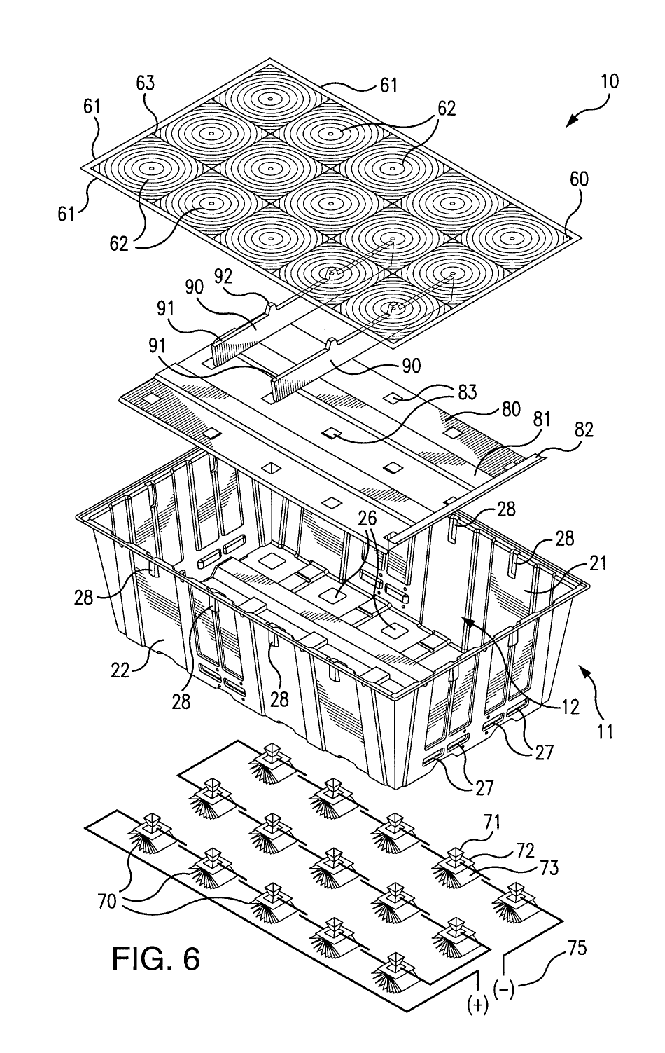

The present application is directed to solar cell modules 10 for use in a terrestrial solar tracking photovoltaic array 100. The modules 10 include a housing 11 formed from three separate members that are attached together to form an interior space. A top member 60 extends across an open side of the housing 11 and includes one or more lenses 62. One or more solar cell receivers 70 (see FIG. 6) are positioned within the interior space of the housing 11 and are aligned with one or more of the lenses 62 to receive and convert the solar energy into electrical energy.

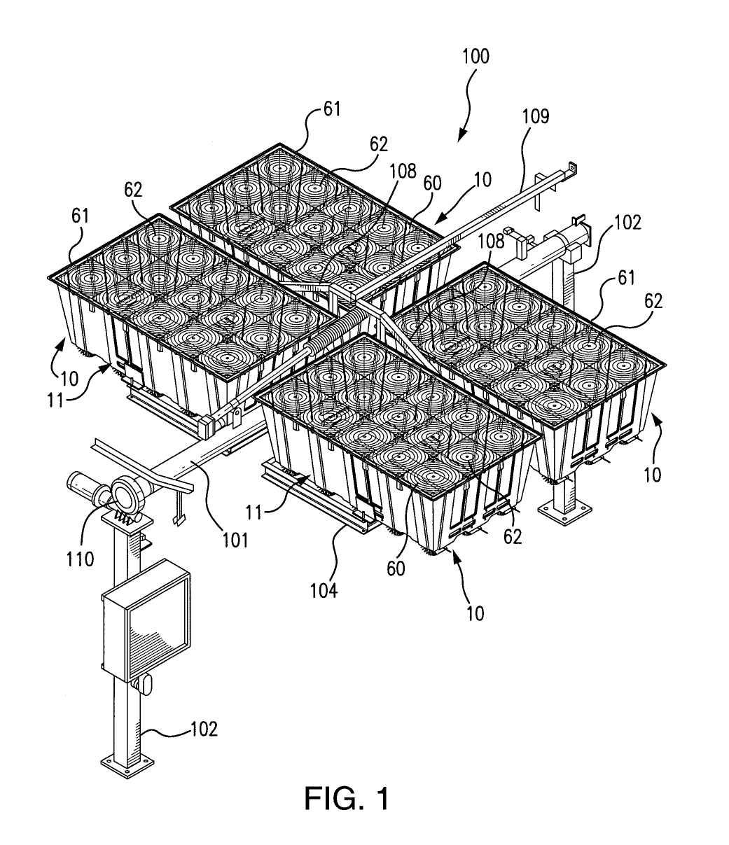

The solar cell modules 10 (hereinafter modules 10) are mounted on the terrestrial solar tracking photovoltaic array 100 (hereinafter array 100) to track the sun. FIG. 1 illustrates a portion of an array 100 that supports the modules 10. The array 100 includes an elongated torque tube 101 supported by vertical supports 102. The array 100 further includes one or more mounts 104 extending outward from the torque tube 101 to support the modules 10. The array 100 is configured to rotate the modules 10 along a first axis that extends through the torque tube 100 to simultaneously track the elevation of the sun during the course of a day. The array 100 is also configured to rotate the modules 10 about a second axis formed by the mounts 104 that is perpendicular to the first axis to track the azimuthal position of the sun during the course of the day.

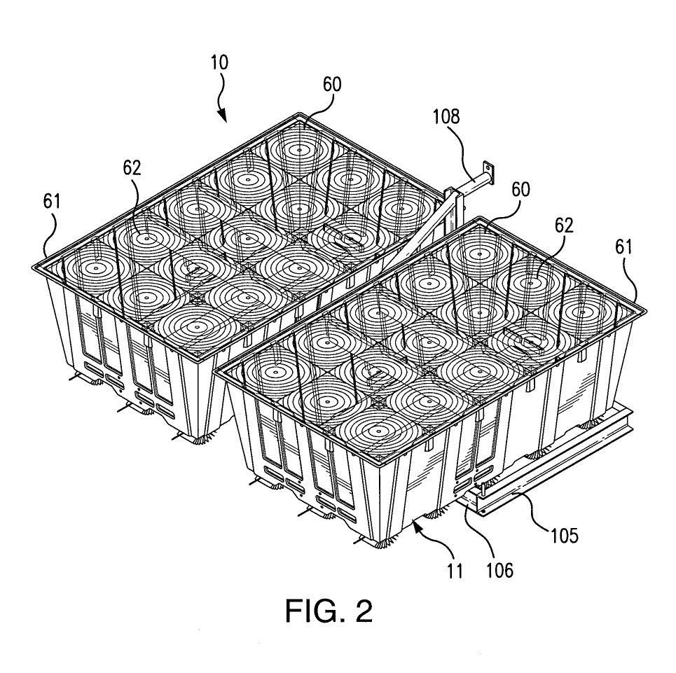

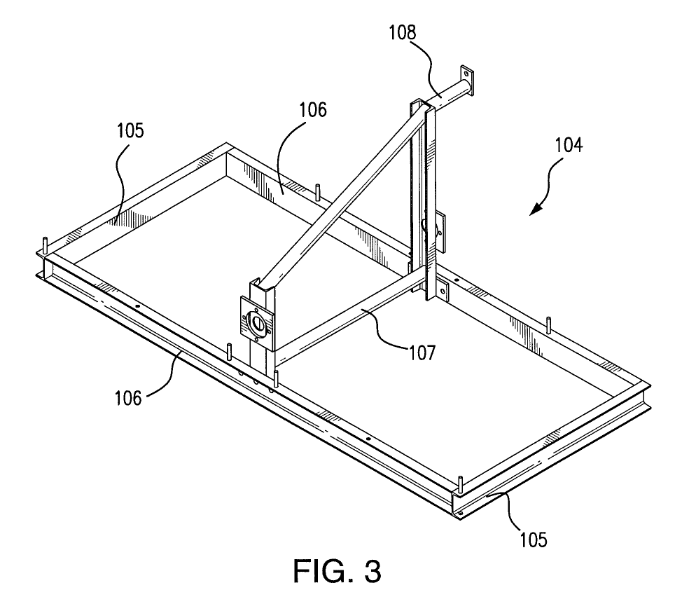

The mounts 104 support the modules 10 and are connected to the torque tube 101. FIGS. 1, 2, and 3 illustrate an embodiment of the mount 104. The mount 104 may include vertical members 105 and horizontal members 106. Each mount 104 may be configured to accommodate different numbers of modules 10, with FIGS. 1, 2, and 3 include a mount 104 configured to accommodate a pair of modules 10. Mounts 104 may also include a pivot member 107 and attachment 108 that facilitates pivoting motion about the second axes.

A drive 110 is connected to the torque tube 101 to provide a force to rotate the torque tube about the first axis. Drive 110 may include a drive train with one or more gears that engage with the torque tube 101. Additional drives 110 may be connected along the length of the torque tube 101 to provide additional rotational force.

The mounts 104 include an attachment 108 for attaching to a linkage 140 that is aligned substantially parallel to the torque tube 101. The linkage 140 is translated by a drive (not illustrated) that provides a force for moving the linkage 140 and thus pivoting the modules 10 about the second axes.

Embodiments of arrays are disclosed in Ser. No. 12/574,508 filed on Oct. 6, 2009, and herein incorporated by reference in its entirety.

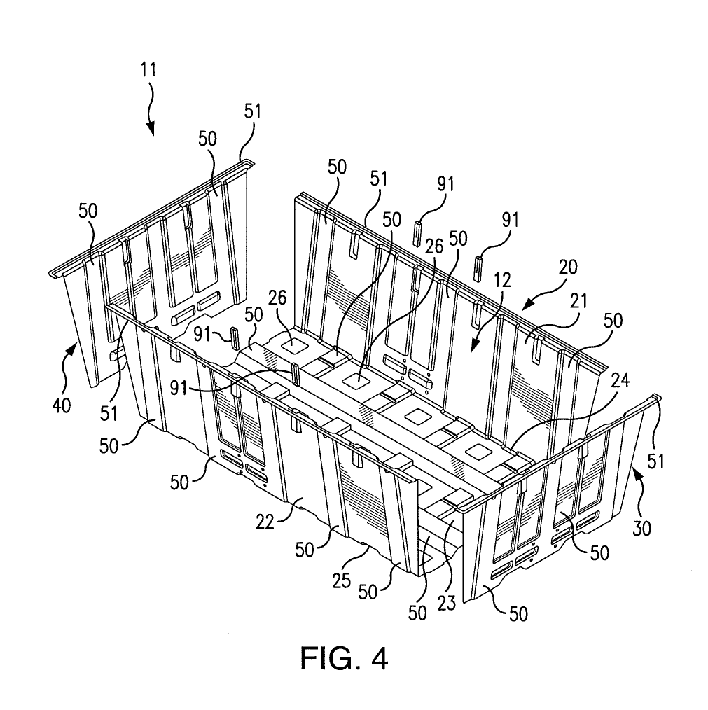

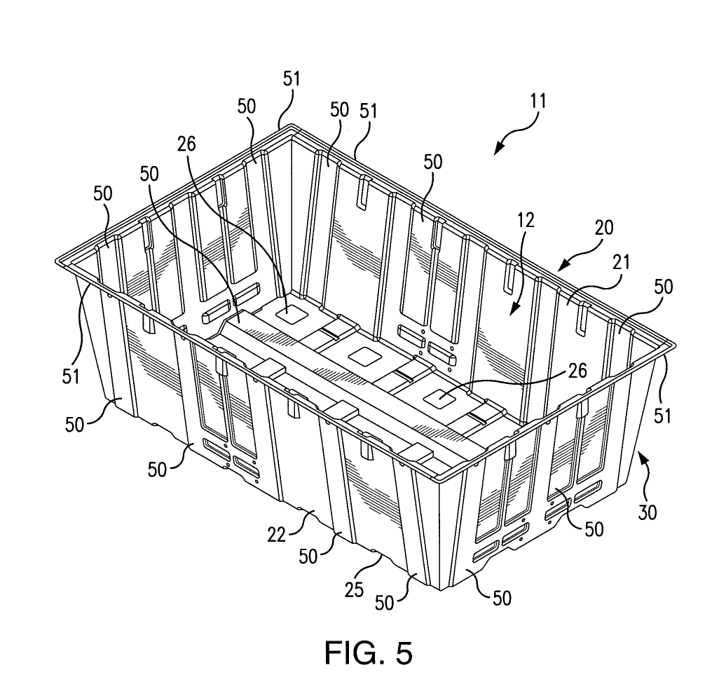

The modules 10 each include a housing 11 that forms a portion of the exterior of the module 10 and provides positioning and protection to the solar cell receivers 70. As illustrated in FIGS. 4 and 5, the housing 11 is formed from three separate pieces: a first member 20; a second member 30; and a third member 40. The pieces 20, 30, 40 are attached together to form an interior space 12. In one embodiment, the module 11 includes five sides, although other embodiments may include more or fewer sides. Each of the members 20, 30, 40 is initially a sheet. In one embodiment, each of the members 20, 30, 40 is an aluminum sheet. In one specific embodiment, each of the sheets has a thickness of about 2 mm.

One or more of the members 20, 30, 40 may include a lip 51 formed at the top side to receive the top member 60. The lips 51 may be formed by stamping or otherwise bending a top portion of the respective members 20, 30, 40.

The first member 20 is larger than either of the second and third members 30, 40. The first member 20 is initially a relatively flat sheet that is stamped or otherwise folded to form opposing lateral sides 21, 22, and a bottom 23. A first fold 24 is formed between the lateral side 21 and the bottom 23, and a second fold 25 is formed between the lateral side 22 and the bottom 23.

Openings 26 may be formed in the bottom side 23 to receive the solar cell receivers 70. The openings 26 may be uniformly distributed along the bottom side 23. The shape and size of the openings 26 may vary. In one embodiment, each of the openings 26 has the same shape and size. Other embodiments may include openings 26 with different shapes and/or sizes. In one embodiment, the openings 26 are stamped from the sheet of material.

The second member 30 is attached to the first exposed ends of the member 20, and the third member 40 is attached to the opposing second exposed ends of the member 20. In one embodiment, the members 30, 40 are welded to the member 20. The separate members 20, 30, 40 create an interior area to position and protect the one or more solar cell receivers 70. The folds 24, 25 and the welds that attach the end members 30, 40 are continuous to prevent the ingress of water in the form of rain, snow, or ice that may contact against the exterior of the module 11.

The sides 21, 22 and members 30, 40 may be positioned perpendicular to the bottom 23. This positioning causes the open side of the housing 11 to be about the same size as the bottom 23. Alternatively, one or more of the sides 21, 22 and members 30, 40 may be angled outward (i.e., form an angle of greater than 90° with the bottom 23). This angled positioning results in the open side of the housing 11 being larger than the bottom 23.

One or more of the members 20, 30, 40 may include ribs 50 that are stamped into the sheet material to increase the strength and rigidity. The ribs 50 include an elongated shape. The ribs 50 along the sides 21, 22 and members 30, 40 may extend along the entire height or a portion of the height between the top side and the bottom 23. Ribs 50 may also extend along the bottom 23 in longitudinal and/or lateral orientations, and may extend across the entirety or portion of the bottom 23. The ribs 50 along the housing 11 may have the same or different shapes and/or sizes. The ribs 50 may also include separate elements that are attached to the members 20, 30, 40.

FIG. 6 includes an exploded view of components of the solar cell module 10. The housing 11 forms the body that supports and positions the other elements. A support member 80 is positioned within the interior space 12 of the housing 11. The support member 80 includes a substantially planar shape with a length and width to fit in proximity to the bottom 23 of the housing 11. The support member 80 may contact against or be spaced away from the bottom 23. The dimensions of the support member 80 may be approximately the same or may be smaller than the bottom 23 to fit within the interior space 12. A flange 82 may extend along one or more sides to position the support member 80 within the interior space 12. The flange 82 may engage with features 27 of the housing 11 to position the support member 80. The support member 80 may include one or more ribs 81 to strengthen and increase the rigidity. The support member 80 may also include one or more openings 83 that align with the openings 26 in the bottom 23.

The support member 80 may further act as a shield to prevent focused solar energy from directly impinging upon the solar cell receivers 70 at areas outside of the designed areas.

One or more braces 90 may extend across the interior space 12 to further support the housing 11. The braces 90 include an elongated shape with opposing ends that fit within slots 28 in the housing 11. As illustrated in FIG. 6, the braces 90 include first ends that fit within slots 28 in the first side 21 and second ends that fit within slots 28 in the second side 22. Clips 91 (see FIG. 4) may be sized to fit into the slots 28 to secure the braces 90.

The braces 90 may also be positioned to contact against and support the top member 60. One of the sides 91 of the braces 90 face upward and may contact against the inner surface of the top member 60. The sides 91 may also include protrusions 92 to further contact against the top member 60.

The top member 60 extends across the open side of the housing 11. In the embodiment illustrated, the outer edges 61 of the top member 60 seat within the lips 51 formed around the upper side of the housing 11. The top member 60 may be attached to the housing 11 by an adhesive and/or one or more mechanical fasteners such as but not limited to screws, bolts, and rivets.

The top member 60 includes a number of lenses 62 that focus the solar energy towards the solar cell receivers 70 within the interior space 12 of the housing 11. In one embodiment, each of the lenses 62 directs solar energy to a specific solar cell receiver 70 positioned below the lens. In one embodiment, the top member 60 includes a total of fifteen lenses 62 that includes three rows of five lenses 62.

Each of the lenses 62 may have the same or different construction, size, or shape. One specific embodiment includes each of the lenses 62 being identical. The lenses 62 may be Fresnel lenses or may be conventional spherical lenses. An advantage of Fresnel lenses is they require less material compared to a conventional spherical lens. In one embodiment, each lens 62 has a rectangular shape. In a specific embodiment, each lens is about 9 inches by 9 inches. The lenses 62 may be constructed from different materials, including but not limited to acrylic, plastic, and glass. Each lens 62 may further include an anti-reflective coating.

The top member 60 may be formed as a sheet 63 and sized to extend across the open side of the housing 11. The sheet 63 includes a series of openings each sized to receive one of the lenses 62. The sheet 63 may be formed from various materials, including but not limited to plastic, acrylic, and aluminum. The top member 60 also extends across the open side of the housing 11 and prevents the ingress of water, rain, or ice into the interior space 12.

One embodiment of a top member with a plurality of lenses is disclosed in US Patent Publication No. 2010/0011565 herein incorporated by reference in its entirety.

Solar cell receivers 70 are positioned in the interior space 12 of the housing 11 and aligned with the lenses 62. Each of the solar cell receivers 70 includes a secondary optical element 71, a solar cell 72, and a heat sink 73. The arrangement of the solar cell receivers 70 may match that of the lenses 62. In one embodiment, the solar cell receivers 70 are arranged in an array of three rows each with five solar cell receivers 70 that correspond to the paired arrangement of the lenses 62 in the top member 60.

The secondary optical element 71 is positioned between the paired lens 62 and the solar cell 72. The secondary optical element 71 includes an inlet that faces towards the paired lens 62 and an outlet that faces towards the paired solar cell 72. The secondary optical element 71 collects solar energy concentrated by the corresponding lens 62 and directs it to the solar cell 72. The secondary optical element 71 may be made of metal, plastic, glass, or other materials.

Each of the solar cells 72 may be a triple-junction III-V compound semiconductor solar cell which comprises a top cell, a middle cell and a bottom cell arranged in series. In one embodiment, the solar cells 72 are multijunction solar cells having n-on-p polarity and is composed of InGaP/(In)GaAs III-V compounds on a Ge substrate. In each case, the solar cells 72 are positioned to receive focused solar energy from secondary optical element 71 and the corresponding lens 62. The solar cells 72 may also include an anti-reflective coating.

A concentrator may also be positioned between the secondary optical element 71 and the solar cell 72. The concentrator includes an optical inlet that faces towards the secondary optical element 71 and an optical outlet that faces towards the solar cell 72. In one embodiment, the concentrator is solid glass. The concentrator amplifies the light exiting the secondary optical element 71 and directs the amplified light toward the solar cell 72.

The heat sink 73 is operatively connected to the solar cell 72. The heat sink 73 may include a base and one or more outwardly-extending wings.

As illustrated in FIG. 6, the solar cell receivers 70 are connected in series. An end connector 75 is positioned on a side of the module 10.

Embodiments of solar cell receivers are disclosed in US Patent Publication No. 2011/0048535, herein incorporated by reference in its entirety.

The housing 11 may be configured for accurate alignment of each of the solar cell receivers 70 relative to its paired lens 62. In one embodiment, the solar cell receivers 70 are mounted through the bottom side 23 of the housing 11 with the heat sink 73 positioned outward beyond the bottom side 23. The solar cell 72 and the secondary optical element 71 extend through one of the openings 26 in the bottom 23 and one of the openings 83 in the sun shield member 80 and are positioned within the interior space 12. The sunshield member 80 is positioned on top of the receivers 70, with the secondary optical element 71 extending through the openings 83 therein. The size of the heat sink 73 and/or the solar cell receiver 70 extends across and plugs the openings 26 to prevent the ingress of water into the interior space 12. The solar cell receivers 70 may be attached to the housing 11 by adhesives and/or mechanical fasteners.

The housing 11 has a height measured between the bottom side 23 and the top member 60 to provide for accurate placement of each of the solar cell receivers 70 relative to the paired lens 62. This distance may be based on the focal length of the lens 62 with one embodiment positioning each respective solar cell receiver 70 disposed at or about the focal point away from the respective lens 62. The focal lengths of the lenses 62 may range from between about 25.4 cm (10 inches) and 76.2 cm (30 inches), with specific embodiments including focal lengths of between about 38.1 cm (15 inches) and 50.8 cm (20 inches). One specific embodiment includes a focal length of about 40.085 cm (17.75 inches).

The housing 11 may also include one or more vent openings to allow air to move into and out of the interior space 12. A filter, such as a GORETEX fabric, may extend across the vent openings to prevent water from penetrating into the interior space 12.

While particular embodiments of the present invention have been shown and described, it will be understood by those skilled in the art that, based upon the teachings herein, changes and modifications may be made without departing from this invention and its broader aspects and, therefore, the appended claims are to encompass within their scope all such changes and modifications as are within the scope of this invention. Furthermore, it is to be understood that the invention is solely defined by the appended claims.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” “comprise” and variations thereof, such as, “comprises” and “comprising” are to be construed in an open, inclusive sense, that is as “including, but not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

What is claimed is:

1. A method of forming a solar cell module for use in a terrestrial solar tracking photovoltaic array, the method comprising:
deforming an enlarged first sheet into three substantially planar sections including a bottom side and opposing first and second lateral sides, the lateral sides being transverse to the bottom side;
attaching a second sheet to exposed first ends of the bottom side and the lateral sides, the second sheet being smaller than the first sheet;
attaching a third sheet to exposed second ends of the bottom side and the lateral sides, the third sheet being smaller than the first sheet;
positioning a plurality of solar cell receivers at the bottom side, each of the plurality of solar cell receivers including a solar cell; and
attaching a top member to exposed upper ends of each of the lateral sides, second sheet, and third sheet, the top member including a plurality of lenses with each of the lenses aligning with one of the corresponding solar cell receivers.

2. The method of claim 1, wherein deforming the enlarged first sheet into three substantially planar sections includes forming a first fold between the bottom side and the first lateral side and forming a second fold between the bottom side and the second lateral side with the first and second folds being parallel.

3. The method of claim 2, wherein each of the first and second lateral sides are perpendicular to the bottom side.

4. The method of claim 1, further comprising forming openings in the bottom side and positioned each of the plurality of solar cell receivers within one of the openings.

5. The method of claim 4, further comprising positioning a heat sink of each of the plurality of solar cell receivers outward below the bottom side.

6. The method of claim 1, the solar cell of each of the plurality of solar cell receivers includes a III-V solar cell.

7. The method of claim 1, further comprising forming ribs in at least one of the first, second, and third sheets.

8. A method of forming a solar cell module for use in a terrestrial solar tracking photovoltaic array, the method comprising:
constructing a housing from a first sheet forming three sides of the housing, a second sheet that forms a fourth side of the housing, and a third sheet that forms a fifth side of the housing, the housing forming an interior space with a bottom and outwardly extending sides with an open top side opposite from the bottom side;
positioning a plurality of solar cells receivers through openings in the bottom side, each of the solar cell receivers including a solar cell that is positioned within the interior space and a base positioned out of the interior space; and
attaching a top member across the open top side and enclosing the interior space.

9. The method of claim 8, further comprising aligning a plurality of lenses in the top member with the plurality of solar cell receivers with each one of the plurality of lenses being aligned with a corresponding one of the solar cell receivers.

10. The method of claim 8, further comprising deforming the first sheet and making a first fold that separates the bottom side from a first lateral side and a second fold that separates the bottom side from a second lateral side.

11. The method of claim 8, further comprising positioning braces across the interior space and in contact with opposing ones of the outwardly extending sides and contacting the top member against the braces.

12. The method of claim 8, further comprising positioning a planar support member across the interior space between the bottom side and the top member, the support member including a plurality of openings each sized to receive one of the plurality of solar cell receivers.

13. The method of claim 8, further comprising positioning a heat sink on each of the plurality of solar cell receivers below the bottom side and out of the interior space.

14. The method of claim 8, further comprising angling the outwardly-extending sides away from a center of the interior space such that the open side is larger than the bottom side.

15. A method of forming a solar cell module for use in a terrestrial solar tracking photovoltaic array, the method comprising:
constructing a first portion of a housing by deforming an enlarged first sheet into three substantially planar sections including a bottom side and opposing first and second lateral sides, with a first angled section between the bottom side and the first lateral side and a second angled section between the bottom side and the second lateral side;
attaching a first end member to exposed first ends of the bottom side and the lateral sides;
attaching a second end member to second ends of the bottom side and the lateral sides with the housing forming an interior space between the bottom side and the lateral sides and the end members that extend outward above the bottom side, the housing having an open top side opposite from the bottom side;
attaching a plurality of solar cells receivers to the bottom side, each of the solar cell receivers including a solar cell that is positioned within the interior space; and
attaching a top member to exposed upper ends of each of the lateral sides and the end members, the top member including a plurality of lenses with each of the lenses aligning with one of the corresponding solar cell receivers.

16. The method of claim 15, further comprising forming openings in the bottom side that are each sized to receive one of the solar cell receivers.

17. The method of claim 15, wherein attaching the first and second members to the first portion of the housing includes soldering the end members to the first portion.

18. The method of claim 15, further comprising forming the housing in a manner to prevent the ingress of water into the enclosed interior space.

19. The method of claim 15, further comprising positioning a heat sink on each of the plurality of solar cell receivers below the bottom side and out of the interior space.

20. The method of claim 15, further comprising positioning a support member in the interior space between the bottom side and the top member, the support member including a plurality of openings each sized to receive one of the solar cell receivers.
